(19) United States
(12) Patent Application Publication
(10) Pub. No.: US 2008/0212666 A1
(43) Pub. Date: Sep. 4, 2008

(54) Interference rejection in radio receiver

(75) Inventors: Kiran Kuchi, Irving, TX (US); Olli Piirainen, Oulu (FI); Olav Tirkkonen, Helsinki (FI)

Correspondence Address: SQUIRE, SANDERS & DEMPSEY L.L.P., 8000 TOWERS CRESCENT DRIVE, 14TH FLOOR, VIENNA, VA, 22182-6212, US

(73) Assignee: NOKIA CORPORATION

(21) Appl. No.: 11/712,474

(22) Filed: Mar. 1, 2007

(51) Int. Cl. H03K 5/159

(52) U.S. Cl. 375/231

(57) ABSTRACT

An interference rejection algorithm for a radio receiver is presented. According to the present solution a signal comprising a training sequence and a data sequence is received at the radio receiver. A radio channel response may be estimated from the received training sequence, and interference parameters may be estimated from at least one of the received training sequence and the received data sequence, the estimation of the interference parameters comprising smoothing a frequency spectrum of at least one of the estimated channel response and the estimated interference parameters through averaging. Then, frequency domain interference suppression weights are calculated from the estimated channel response and the interference parameters, and weighting of the received data sequence is carried out with the calculated weights.

### FIELD

The invention relates to interference rejection in a radio receiver.

### BACKGROUND

Radio signals transmitted over an air interface suffer typically from noise and interference caused by multipath propagation, other radio signals on the same frequency band, and thermal noise. If these types of interference are not suppressed at the reception, recovery of transmitted data may not be possible at a receiver. Additionally, the interference typically sets a limit for the capacity of a radio telecommunication system.

Interference rejection combining (IRC) is known as an interference suppression method in a radio receiver utilizing multiple reception diversity branches. A transmitted radio signal is received through each of the reception diversity branches. IRC is a method for determining combining weights to be used when combining the signals received through different diversity branches. IRC typically utilizes the correlation of interference and noise between the diversity branches when determining the combining weights.

A typical solution for IRC is to estimate first a radio channel impulse response from a received training sequence. The received training sequence typically includes a transmitted training sequence, modified by the channel impulse response, and an interference plus noise component. The transmitted training sequence is known to the radio receiver. When the radio channel impulse response has been estimated, the known transmitted training sequence is modified with the estimated impulse response and subtracted from the received training sequence. Accordingly, a residual signal comprises the interference plus noise component and residuals of the training sequence (assuming that the estimation was not perfect). An interference covariance matrix is then calculated from the residual signal, and the combining weights are calculated on the basis of the interference covariance matrix.

Base stations of modern wireless telecommunication systems typically utilize multiple antennas for reception of radio signals from mobile terminals. These antennas can be used for rejecting co-channel interference (CCI) degrading the quality of a desired radio signal received through the antennas. The antennas may be used for multi-user detection, too. In both cases, it is beneficial to use a noise pre-whitening filter to ensure reliable detection of the desired signal in CCI limited cases. In general, co-channel interference suppression through noise whitening has always been a challenging problem. Particularly in broadband channels, e.g. 5 MHz, IRC design is a challenge. Basically, there are two main problems. The number of parameters that is needed to implement a noise-whitening filter can be very large, and typically the noise variance of estimated filter coefficients rises with the length of the noise-whitening filter. Moreover, most of the existing IRC algorithms have either sub-optimum performance or they result in very complex receiver structures. Therefore, there is a need for simplified yet effective interference rejection algorithms.

### BRIEF DESCRIPTION OF THE INVENTION

It is thus an object of the present invention to provide an improved solution for interference rejection in a radio receiver.

According to an aspect of the invention, there is provided a method, comprising: receiving a signal comprising a training sequence and a data sequence, estimating a channel response from the received training sequence and interference parameters from at least one of the received training sequence and the received data sequence, smoothing a frequency spectrum of at least one of the estimated channel response and the estimated interference parameters through averaging, calculating frequency domain interference suppression weights from the estimated channel response and the interference parameters, and weighting the received data sequence with the calculated weights.

According to another aspect of the invention, there is provided an apparatus, comprising an interface to receive a signal comprising a training sequence and a data sequence. The apparatus further comprises a processing unit configured to estimate a channel response from the received training sequence and interference parameters from at least one of the received training sequence and the received data sequence, to smooth a frequency spectrum of at least one of the estimated channel response and the estimated interference parameters through averaging, to calculate frequency domain interference suppression weights from the estimated channel response and the interference parameters, and to weight the received data sequence with the calculated weights.

According to yet another aspect of the invention, there is provided an apparatus, comprising: means for receiving a signal comprising a training sequence and a data sequence, means for estimating a channel response from the received training sequence and interference parameters from at least one of the received training sequence and the received data sequence, means for smoothing a frequency spectrum of at least one of the estimated channel response and the estimated interference parameters through averaging, means for calculating frequency domain interference suppression weights from the estimated channel response and the interference parameters, and means for weighting the received data sequence with the calculated weights.

According to another aspect of the invention, there is provided a computer program distribution medium readable by a computer and encoding a computer program of instructions for executing a computer process for interference rejection. The process comprises: receiving a signal comprising a training sequence and a data sequence, estimating a channel response from the received training sequence and interference parameters from at least one of the received training sequence and the received data sequence, smoothing a frequency spectrum of at least one of the estimated channel response and the estimated interference parameters through averaging, calculating frequency domain interference suppression weights from the estimated channel response and the interference parameters, and weighting the received data sequence with the calculated weights.

### LIST OF DRAWINGS

In the following, the invention will be described in greater detail with reference to the embodiments and the accompanying drawings, in which

FIG. 1 illustrates a structure of a system and apparatuses to which embodiments of the invention may be applied;

FIG. 2 illustrates a radio receiver structure according to an embodiment of the invention;

FIG. 3 illustrates interference parameter estimation according to an embodiment of the invention, and

FIG. 4 is a flow diagram illustrating an interference suppression process according to an embodiment of the invention.

### DESCRIPTION OF EMBODIMENTS

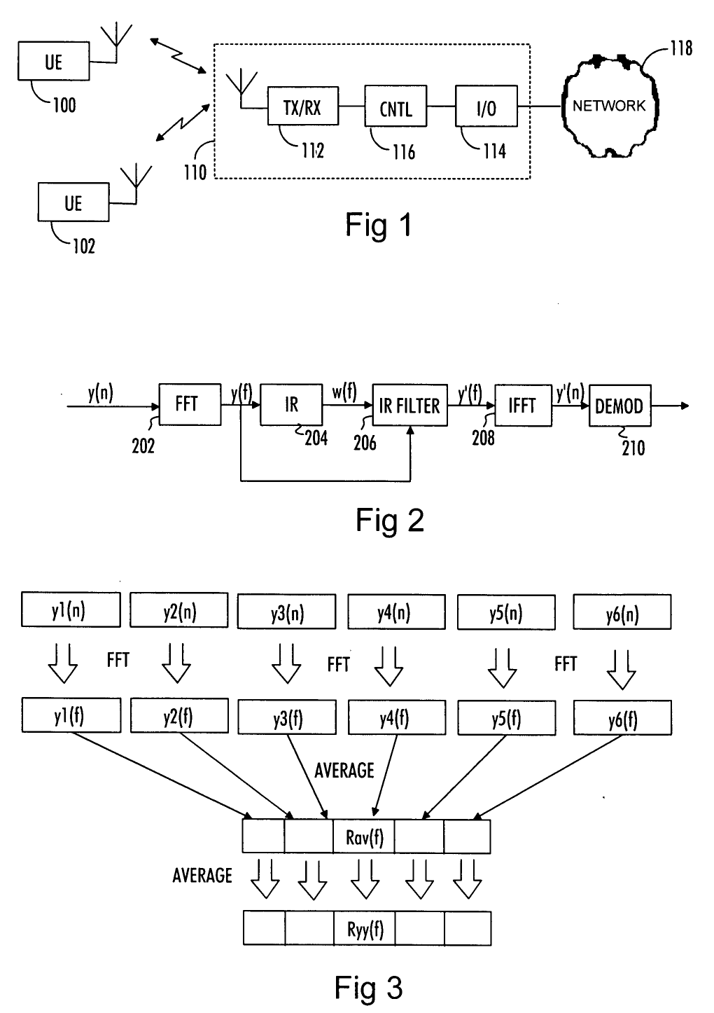

With reference to FIG. 1, let us examine an example of a telecommunication system to which embodiments of the invention can be applied. A mobile subscriber unit 100 communicates wirelessly with a base station 110 over a wireless communication link. The communication may be based on single carrier frequency division multiple access (SC-FDMA) or orthogonal frequency division multiple access (OFDMA) systems that can also be called Enhanced UMTS Terrestrial Radio Access Network (EUTRAN), 3.9G, and longterm evolution (LTE) systems. The communication may equally be based on wideband code division multiple access (W-CDMA).

The base station 110 may be a base transceiver station of a mobile communication system utilizing one or more of the communication schemes listed above. The base station 110 comprises a first communication interface 112 to provide an air interface connection to one or several mobile subscriber units 100, 102. The first communication interface 112 may comprise a plurality of antennas to enable diversity reception of radio signals. The first communication interface 112 may perform analog operations necessary for transmitting and receiving radio signals. Such operations may comprise analog filtering, amplification, up-/downconversions, and A/D (analog-to-digital) or D/A (digital-to-analog) conversion.

The base station 110 may further comprise a second communication interface 114 to provide a wired connection to the network 118 of the telecommunication system. The network 118 of the telecommunication system may provide connections to other networks, such as the Internet and Public Switched Telephone Network (PSTN).

The base station 110 further comprises a processing unit 116 to control functions of the base station 110. The processing unit 116 handles establishment, operation and termination of radio connections with the mobile subscriber units 100 the base station 110 is serving. The processing unit 116 may also perform signal processing operations to received radio signals. The processing unit 116 may be implemented by a digital signal processor with suitable software embedded in a computer readable medium, or by separate logic circuits, for example with ASIC (Application Specific Integrated Circuit).

The mobile subscriber unit 100 may comprise a communication interface to provide a radio connection with the base station. The communication interface may perform analog operations necessary for transmitting and receiving radio signals.

The mobile subscriber unit 100 may further comprise a processing unit to control functions of the mobile subscriber unit 100. The processing unit may handle establishment, operation and termination of radio connections with the base station. The processing unit may also perform signal processing operations to received radio signals. The processing unit 116 may be implemented by a digital signal processor with suitable software embedded in a computer readable medium, or by separate logic circuits, for example with ASIC (Application Specific Integrated Circuit).

The mobile subscriber unit 100 may additionally comprise a user interface for interaction with a user of the mobile subscriber unit 100. The user interface may comprise a display, a keypad or a keyboard, a loudspeaker, a microphone, etc.

Next, a block diagram of FIG. 2 illustrating a basic structure of a radio receiver according to an embodiment of the invention will be discussed. The radio receiver comprises an interference rejection unit according to an embodiment of the invention. The radio receiver may be the base station 110, the mobile subscriber unit 100, or any other suitable radio receiver. The purpose of the interference rejection unit is to estimate and remove interference from a received data signal in order to facilitate detection and decoding of the data signal. The interference may be estimated from a training sequence transmitted through the same radio environment as the data signal. The training sequence is a sequence known to the interference suppression unit and, therefore, it may estimate a channel impulse response and interference parameters from the received training sequence with an appropriate signal processing algorithm.

Alternatively, the interference rejection unit may operate blindly, i.e. estimate interference parameters from a received data signal vector y(n) whose elements may comprise several copies of the same signal that may be obtained via multiple diversity branches or through over-sampling.

Let us now assume that the data transmission scheme is a SC-FDMA scheme in which data of a single user may be transmitted in a plurality of frequency blocks, i.e. a plurality of frequency bands may be allocated to a single user. Accordingly, the received signal is received in the plurality of frequency blocks.

First, the received data signal vector y(n) may be converted from a time domain into a frequency domain through a fast Fourier transform (FFT) in an FFT unit 202 resulting in a frequency-domain representation of the received data signal vector y(fₖ). Notation fₖ indicates a discrete set of frequencies determined by the length of the FFT, i.e. the frequency resolution of the transform. Accordingly, k=1 to N_{fft}, where N_{fft} denotes the length of the FFT, and y(fₖ) represents the contents of the received signal at frequency bin fₖ. An interference estimation block 204 estimates interference parameters from the converted data signal vector y(fₖ) and calculates frequency domain filter coefficients w(fₖ) which are then output to an interference rejection unit 206. The interference rejection unit 206 receives also the converted data signal y(fₖ), and filters the converted data signal with the filter coefficients w(fₖ) received from the interference estimation block 204. A filtered data signal vector y′(fₖ), from which interference has been suppressed, is converted back into the time domain through inverse FFT (IFF) in an IFFT block 208 resulting in a time domain filtered data signal y′(n). Then, the time domain filtered data signal vector y′(n) is applied to a demodulator 210 for demodulation.

As described above, the interference parameter estimation and interference suppression are carried out in the frequency domain. Frequency domain processing has some advantages over time domain processing. For example, frequency characteristics of interference signals (typically other users of the same telecommunication system) and a radio channel impulse response degrading the quality of a received data signal vary slowly over time. Additionally, some mathematical operations are less complex when carried out in the frequency domain. For example, a convolution in the time domain is simplified into a multiplication in the frequency domain. Instead of FFT (and IFFT), the received signal y(n) may be transformed into the frequency domain with a discrete Fourier transform (DFT).

Now, let us consider the operation of the interference estimation block 204 in more detail. As mentioned above, the interference estimation block 204 may receive a converted data signal vector y(fₖ) as an input signal. The converted data signal vector may be represented as

$$y ( {f}_{k} ) = \underbrace{{h}_{1} ( {f}_{k} ) {x}_{1} ( {f}_{k} )}_{Desired Signal} + \underbrace{{\sum }_{j = 2}^{M} {h}_{j} ( {f}_{k} ) {x}_{j} ( {f}_{k} )}_{CCI} + \underbrace{n ( {f}_{k} )}_{AWGN} , \\ k = 1 , 2 , … , {N}_{FFT} \qquad ( 1 )$$

where h₁ represents a radio channel impulse response experienced by a transmitted data signal x₁. Accordingly, the first component in equation (1) represent the desired signal being corrupted by inter-symbol interference caused by the impulse response h₁. hⱼ represents an impulse response affecting another signal x; transmitted in the same time-frequency channel as the desired signal. Accordingly, the second component represents co-channel interference corrupting the desired signal. A total of M interfering signals exist in the same time-frequency channel as the desired signal, i.e. j=2 to M. The last component n represents additive, white, Gaussian distributed noise. In equation (1), each term is represented in a vector form as a frequency domain representation. The interference estimation block 204 may utilize signals received through multiple reception antennas and/or oversampled with a determined signal oversampling factor, in which cases a plurality of received data signal vectors having a similar form as vector y in equation would be obtained. The number of received data signal vectors depends on the number of diversity branches obtained through multiple antenna reception and/or oversampling, and the received data signal vectors may be represented in a matrix form, as will be described later.

In case of diversity reception or oversampling, elements of equation (1) take the following form:

hⱼ(fₖ)=DFT[{h_{j,1}¹(n)h_{j,1}²(n) . . . h_{j,s}^{N}(n)}]^{T}

y(fₖ)=DFT[{y₁¹(n)y₁²(n) . . . yₛ^{N}(n)}]^{T},

n(fₖ)=DFT[{n₁¹(n) n₁²(n) . . . nₛ^{N}(n)}]^{T}

x(fₖ)=DFT[xⱼ(n)] (2)

where N is the number of reception antennas, s is the oversampling factor, and T denotes a transpose operation. Accordingly, the samples obtained from the diversity branches for a given time index n may be stacked into a single vector together with the over-sampled signal elements to form a single column vector of length Ns. The goal is to seek a coefficient vector w(fₖ) of a minimum mean square error (MMSE) filter that minimizes a mean square error (MSE) term defined according to the following equation:

$$MSE = \frac{1}{{N}_{FFT}} {\sum }_{k = 1}^{{N}_{FFT}} E [ {‖ w ( {f}_{k} ) y ( {f}_{k} ) - {x}_{1} ( {f}_{k} ) ‖}^{2} ] . \qquad ( 3 )$$

The coefficient vector w(fₖ) may be obtained by solving components of the following equation:

w(fₖ)=R_{xy}(fₖ)R_{yy}⁻¹(fₖ), (4)

where R_{xy} is a cross-correlation matrix describing cross-correlation properties between the transmitted data signal vector x₁(fₖ) and the received signal vector y(fₖ). Through simple mathematical procedures, R_{xy} may be simplified into the following form: R_{xy}=N_{FFT}h₁*(fₖ), where * denotes complex conjugate transpose operation. The basis for the simplification is the assumption that the cross-correlation of x, with itself is one. In equation (4), term R_{yy} represents the covariance matrix of the received signal vector, and may be divided into two components according to the following equation:

R_{yy}(fₖ)=E[y(fₖ)y*(fₖ)]=[Rₛₛ(fₖ)+Rᵢᵢ(fₖ)], (5)

where Rₛₛ represents a frequency domain representation of a covariance matrix of the channel vector h₁(fₖ) experienced by the desired data signal x₁(fₖ) and Rᵢᵢ is a frequency domain representation of a covariance matrix, i.e. a power density spectrum, for the co-channel interference component as

$${R}_{ss} ( {f}_{k} ) = {N}_{FFT} {h}_{1} ( {f}_{k} ) {h}_{1}^{*} ( {f}_{k} ) , \\ {R}_{ii} ( {f}_{k} ) = E [ i ( {f}_{k} ) {i}^{*} ( {f}_{k} ) ] \\ where i ( {f}_{k} ) = {\sum }_{j = 2}^{M} {h}_{j} ( {f}_{k} ) {x}_{j} ( {f}_{k} ) . \qquad ( 6 )$$

Using the results described above, equation (4) may be rewritten in the following form:

$$w ( {f}_{k} ) = {{h}_{1}^{*} ( {f}_{k} ) [ {h}_{1} ( {f}_{k} ) {h}_{1}^{*} ( {f}_{k} ) + {\overline{R}}_{ii} ( {f}_{k} ) ]}^{- 1} , where \\ {\overline{R}}_{ii} ( {f}_{k} ) = \frac{{R}_{ii} ( {f}_{k} )}{{N}_{FFT}} . \qquad ( 7 )$$

The channel response term h₁ may be obtained from received pilot symbols or the training sequence, as is known in the art. An alternative expression for equation (7) may be obtained by using a matrix inversion lemma. Then, equation (7) obtains the following expression

w(fₖ)=[1+h₁*(fₖ) R̅ᵢᵢ⁻¹(fₖ)h₁(fₖ)]⁻¹h₁*(fₖ) R̅ᵢᵢ⁻¹(fₖ). (8)

The aim now is to estimate the co-channel interference component (or interference parameters) which may be represented as

$${\hat{\overline{R}}}_{ii} ( {f}_{k} ) = \frac{{\hat{R}}_{yy} ( {f}_{k} )}{{N}_{FFT}} - {\hat{h}}_{1} ( {f}_{k} ) {\hat{h}}_{1}^{*} ( {f}_{k} ) . \qquad ( 9 )$$

Obviously, the aim focuses on the estimation of the received signal frequency domain covariance matrix

$$\frac{{\hat{R}}_{yy} ( {f}_{k} )}{{N}_{FFT}} = \frac{1}{{N}_{FFT}} E [ \hat{y} ( {f}_{k} ) {\hat{y}}^{*} ( {f}_{k} ) ] ,$$

which will be described next. First, let us note that the right hand side of the equation is in the form of a periodogram and denotes an estimate of the frequency domain covariance matrix of the time domain received data signal vector y(n). Periodograms typically exhibit rapid fluctuations in the frequency domain and may increase the variance of estimates. For the purpose of estimating R_{yy}(fₖ) and, particularly, smoothing the periodogram, the received data signal vector y(n) may be divided into a determined number of segments. Referring to FIG. 3, the data signal y(n) is now divided into six segments y1(n) to y6(n) constituting the received data signal y(n). Each segment y1(n) to y6(n) may be transformed into the frequency domain separately, i.e. a separate FFT may be calculated for each segment y1(n) to y6(n) in the FFT block 202. As a result, transformed signal vectors y1(f) to y6(f) are obtained. The transformed signal vectors y1(f) to y6(f) represent the frequency contents of the received signal vectors y1(n) to y6(n), respectively.

Then, a power density spectrum may be calculated from each transformed signal vector y1(f) to y6(f). The frequency domain covariance matrix may be calculated by multiplying a transformed signal vector with its complex conjugate transpose. For example, frequency domain covariance matrix R1(f) for transformed signal vector y1(f) may be calculated as R1(f)=y1(f) y1*(f). Similarly, frequency domain covariance matrices R2(f) to R6(f) are calculated from the transformed signal vectors y1(f) to y6(f).

Then, the frequency domain covariance matrices R1(f) to R6(f) may be smoothed through averaging. The averaging may be carried out over the frequency domain covariance matrices R1(f) to R6(f), i.e. an average value may be calculated from the corresponding elements of the matrices R1(f) to R6(f), thereby obtaining an averaged frequency domain covariance matrix Rₐᵥ(f). The segments y1(n) to y6(n) may naturally be formed in another way. Additionally, the number of segments may be any other than six. The point is that the received signal y(n) is divided into a number of disjoint segments, each segment is transformed into the frequency domain, and the frequency domain covariance matrices of the segments are averaged to obtain the averaged frequency domain covariance matrix Rₐᵥ(f).

In addition to the averaging described above, another averaging operation may be carried out in order to further reduce the variance of the estimate. The second averaging may be performed over frequency. The averaged frequency domain covariance matrix may be divided in frequency into frequency sub-blocks, each having a determined bandwidth. The second averaging may be carried out over each frequency sub-block. That is, from the samples of each frequency sub-block, an average value is calculated to represent an average covariance matrix in the frequency sub-block. As a result, a set of average frequency domain covariance matrix values is obtained and this set forms \hat{R}_{yy}(fₖ) for all k, which was the target of the estimation. In the form of an equation, an averaged frequency domain covariance matrix \hat{R}_{yy}(f_{q}) for a given frequency sub-block q may be defined as

$${R}_{yy} ( {f}_{q} ) = \frac{1}{{KL}_{cut}} {\sum }_{p = 1}^{{L}_{cut}} {\sum }_{l = 1}^{K} {y}_{1 , q} ( {f}_{p} ) {y}_{1 , q}^{*} ( {f}_{p} ) , q = 1 , 2 , … [ \frac{{N}_{FFT}}{{L}_{cut}} ] , \qquad ( 10 )$$

where L_{cut} is the bandwidth of the frequency sub-block in terms of frequency bins and p=1,2, . . . ,L_{cut}. K denotes the number of segments. In equation (10), it is assumed that the transformed data vector y(fₖ) is divided into [N_{FFT}/L_{cut}] contiguous frequency sub-blocks, and the frequency domain covariance matrix of the interference component is assumed to remain constant within each frequency sub-block. Therefore, the modified notation of equation (10) is used to denote the transformed data vector y.

Now that we have estimated the averaged frequency domain covariance matrix \hat{R}_{yy}(f_{q}) for each frequency sub-block, we have all the tools to calculate equation (8). The co-channel interference component

$${\hat{\overline{R}}}_{ii}$$

may be estimated for each frequency sub-block q separately according to equation (9) from the average frequency domain covariance matrices calculated according to equation (10). As mentioned above, the channel response h₁(fₖ) may be estimated from the received training sequence. The channel response may also be divided into frequency sub-blocks having bandwidth L_{cut} and averaged over each frequency sub-block to obtain a block-wise averaged channel response as

$${\hat{h}}_{1} ( {f}_{q} ) = {\sum }_{p = 1}^{{L}_{cut}} {h}_{1 , q} ( {f}_{p} ) . \qquad ( 11 )$$

Then, equation (9) may be calculated for each frequency sub-block q to obtain an interference-plus-noise-covariance estimate. In more detail, the effect of the estimated channel response ĥ₁(f_{q}) of the desired signal is removed from the received signal frequency domain covariance matrix (divided by the length of the FFT) in equation (9) to obtain covariance information which contains the interference component without the channel component. Then, the covariance estimates

$${\hat{\overline{R}}}_{ii} ( {f}_{q} )$$

may be combined into a single matrix

$${\hat{\overline{R}}}_{ii} ( {f}_{k} ) ,$$

and then the coefficient vector w(fₖ) may be calculated according to equation (8), for example. After the coefficient vector w(fₖ) has been calculated, the coefficient vector w(fₖ) may be fed to the interference rejection unit 206 which weights the transformed received data signal vector y(fₖ) with the coefficient vector w(fₖ) by multiplying the corresponding elements of the vectors y(fₖ) and w(fₖ). Then, the resulting signal may be applied to the inverse FFT block for inverse FFT, and symbol demodulation and detection may be carried out according to a method known in the art.

The embodiment of the invention above was described in the context of estimating the interference parameters blindly, i.e. no knowledge about the transmitted desired signal was utilized. Accordingly, the embodiment described above may estimate the interference parameters from a received data signal. This embodiment was described for the sake of simplicity of the description. A preferred embodiment of the invention utilizes the training sequence for the estimation of the interference parameters. In the preferred embodiment, the known transmitted training sequence modified with the estimated channel response ĥ₁(fₖ) may be removed from the received signal to obtain an interference signal vector according to the following equation:

i(fₖ)=y(fₖ)−ĥ₁(fₖ)x(fₖ) (12)

Once the interference signal vector i(fₖ) has been estimated, the received and transformed data signal vector y(fₖ) in the relevant equations (9) and (10) is replaced with the interference signal vector i(fₖ). In other words, instead of the frequency domain covariance matrix of the received signal y(fₖ), a frequency domain covariance matrix of the interference i(fₖ) is calculated.

When calculating the coefficient vector w(fₖ) according to equation (8), for example, the estimated channel response ĥ(fₖ) is used. In practice this estimated channel response may be calculated from the training sequence according to an estimation procedure known in the art and, thus, it represents estimated values for each frequency bin. In order to further reduce the complexity of the present algorithm, the coefficient vector w(fₖ) may also be calculated on a frequency sub-block level by replacing the per bin channel response vector ĥ₁(fₖ) with the frequency sub-block wise averaged channel response ĥ₁(f_{q}) calculated according to equation (11). Naturally, this simplification applies to both blind and pilot-assisted interference estimation.

Performance of the embodiments described above may be improved by further modifying the averaged frequency domain covariance matrix and/or the averaged channel response which have been averaged on the frequency sub-block level. As described above, an average value is calculated for each frequency sub-block and these average values are used in the estimation. The performance of this scheme is at its best when the interference-plus-noise spectrum is flat within one frequency sub-block. In order to better follow an interference-plus-noise spectrum which is non-flat within the whole frequency band of the received signal y(fₖ), additional values may be interpolated for frequency components (bins) between the contiguous frequency components having an average value. In more detail, the calculated average values may be chosen for a given number of frequency bins around a center frequency of a frequency sub-block, and values for the other frequency bins may be interpolated from the average values of contiguous frequency sub-blocks. In other words, additional values may be calculated between the center frequencies of two contiguous frequency sub-blocks from the average values of the two frequency sub-blocks calculated according to equation (10) for the interference and/or equation (11) for the channel response. The selection of the bandwidth of the frequency sub-blocks, i.e. the selection of L_{cut}, may be made according to the following equation:

$${L}_{cut} = \frac{{N}_{FFT}}{L} , \qquad ( 13 )$$

where L is the length of a radio channel impulse response which may be estimated before calculating equation (10). Alternatively, since the co-channel interference is typically caused by the other users of the same system and the bandwidths of the co-channel interferers are typically known parameters, the bandwidth of the frequency sub-blocks L_{cut} may be chosen to be equal to the lowest of the bandwidths of the co-channel interferers or a multiple of the lowest bandwidth in order to isolate the interferers in the frequency domain and to perform the whitening operation to suppress each interferer individually in the frequency domain on the frequency sub-block level.

In the description above, two averaging processes are mentioned. The first averaging process was carried out by averaging the frequency domain covariance matrices R1(f) to R6(f), and the second averaging was carried out by dividing the total bandwidth into the frequency sub-blocks and averaging the contents of each frequency sub-block. Both averaging processes may not, however, be necessary in some implementations. According to another embodiment of the invention, only one of the two above-mentioned averaging processes may be carried out in order to smoothen the periodogram. If only the first averaging process is to be used, the averaged frequency domain covariance matrix \hat{R}_{yy} would not be divided into frequency sub-blocks and the first summation in equation (10) would be omitted. In other words, the averaged frequency domain covariance matrix \hat{R}_{yy} is calculated jointly for all frequencies. On the other hand, if only the second averaging is to be utilized, the received data may be formed into a single vector y(n), and the FFT may be calculated for that vector y(n). Then, the division into frequency sub-blocks may be made and equation (10) calculated by omitting the second summation. In other words, the division into segments as described above would be omitted in this case.

In the above description of a preferred embodiment of the invention, the channel response and the interference parameters (covariance matrix) are estimated from the transform-domain samples of the received training sequence and the data sequence. Alternatively, the channel response and the interference parameters may be estimated from the time domain samples of the received training sequence (the interference parameters may be estimated also blindly from the time domain data sequence), and the estimates may then be transformed into the frequency domain for averaging. The division into segments and averaging over the segments functions with this embodiment, too. Obviously, the received training or data sequence may be divided into segments, and the interference parameters may be estimated for each segment separately. Then, the estimates may be transformed into the frequency domain and averaged. Naturally, the second averaging, i.e. division of the frequency domain estimates of the channel response and/or the interference covariance matrix into a frequency sub-block and averaging within each frequency sub-block, may be applied to this embodiment as well.

Embodiments of the invention also apply to a multiple-input-multiple-output (MIMO) and virtual MIMO data reception. In the virtual MIMO configuration, two (or more) distinct users are assigned with the same time-frequency channel. Therefore, the users cause mutual interference. At the base station, the signals of the users may be separated with a receiver structure utilizing multiple reception antennas. In the virtual MIMO configuration, the users are transmitting with single antennas and act as multiple (virtual) antennas. Training sequences (pilot signals) of the users allocated to the same time-frequency channel may be designed to be orthogonal to ensure that the base station receiver may estimate channel state information of the users reliably. Unlike the MMSE receiver described above that processes each user separately and treats the other users as co-channel interference, it is possible to define a MIMO receiver that explicitly takes into account the channel state information on the users allocated to the same time-frequency channel. Let us in this example assume that two users share the same time-frequency channel, and an interference rejection algorithm at the base station jointly processes signals received from the two users. Accordingly, the frequency domain representation of a signal received at the base station may be defined as

$$y ( {f}_{k} ) = \underbrace{{h}_{1} ( {f}_{k} ) {x}_{1} ( {f}_{k} ) + {h}_{2} ( {f}_{k} ) {x}_{2} ( {f}_{k} )}_{Desired Signal} + \underbrace{{\sum }_{j = 3}^{M} {h}_{j} ( {f}_{k} ) {x}_{j} ( {f}_{k} )}_{CCI} + \underbrace{n ( {f}_{k} )}_{AWGN} , \qquad ( 14 )$$

where k=1,2, . . . , N_{FFT} and x₁(fₖ) and x₂(fₖ) represent frequency contents of signals transmitted from the two users (x₁ from a first user and x₂ from a second user) and, particularly, the frequency contents of frequency fₖ. The transmitted signals are corrupted by respective radio channel impulse responses ha and h₂. The transmitted signals affected by the channel impulse responses are considered to be desired signals and the remaining signals are treated as co-channel interference and noise. Equation (14) may be represented in a matrix form as

$$y ( {f}_{k} ) = \underbrace{H ( {f}_{k} ) x ( {f}_{k} )}_{Desired Signal} + \underbrace{{\sum }_{j = 3}^{M} {h}_{j} ( {f}_{k} ) {x}_{j} ( {f}_{k} )}_{CCI} + \underbrace{n ( {f}_{k} )}_{AWGN} , where \\ x ( {f}_{k} ) = {[ \begin{matrix}{x}_{1} ( {f}_{k} ) & {x}_{2} ( {f}_{k} )\end{matrix} ]}^{T} , H ( {f}_{k} ) = [ \begin{matrix}{h}_{1} ( {f}_{k} ) & {h}_{2} ( {f}_{k} )\end{matrix} ] . \qquad ( 15 )$$

In this case, the aim is to find a matrix-valued MMSE filter W(fₖ) which minimizes either the trace or the determinant of a matrix-valued mean square error term defined as

$$MSE = \frac{1}{{N}_{FFT}} {\sum }_{k = 1}^{{N}_{FFT}} E [ {‖ W ( {f}_{k} ) y ( {f}_{k} ) - {x}_{1} ( {f}_{k} ) ‖}^{2} ] . \qquad ( 16 )$$

Notice that equation (16) is similar to equation (3) except for the matrix notation for the coefficient weights W(fₖ) of the MMSE filter. The MMSE solution for this case is also analogous to the solution obtained through calculation of equation (8). Accordingly, the coefficient weight matrix W(fₖ) may be obtained according to one of the following equations:

W(fₖ)=[I+H*(fₖ) R̅ᵢᵢ⁻¹(fₖ)+H(fₖ)]¹+H*(fₖ) R̅ᵢᵢ⁻¹(fₖ), (17)

W(fₖ)=H*(fₖ)[H*(fₖ)H(fₖ)+ R̅ᵢᵢ(fₖ)]⁻¹ (18)

where I is an identity matrix. The calculation of the frequency domain covariance matrix estimates \overline{\hat{R}}ᵢᵢ(f_{q}) is similar to that described above except that certain vector calculations become matrix calculations due to the channel response vector h being replaced with the channel response matrix H. The result of weighting the received signal y(fₖ) with the coefficient weight matrix W(fₖ) results in two interference-suppressed signals, each associated with one of the two users.

Symbol demodulation and detection may be carried out for the interference-suppressed signals according to a method known in the art. The symbol demodulation and detection may be carried out jointly for both users, thereby utilizing the correlation properties between the interference-suppressed signals. Alternatively, the symbol demodulation and detection may be carried out separately for each user by using single user demodulators, thereby ignoring the correlation properties between the interference-suppressed signals of the users. As mentioned above, the interference rejection algorithm described above is applicable to many radio telecommunication systems. In SC-FDMA and W-CDMA systems, the receiver structure may be similar to that illustrated in FIG. 2. In OFDMA systems, the IFFT block 208 may be omitted because symbol demodulation and detection are carried out in the frequency domain.

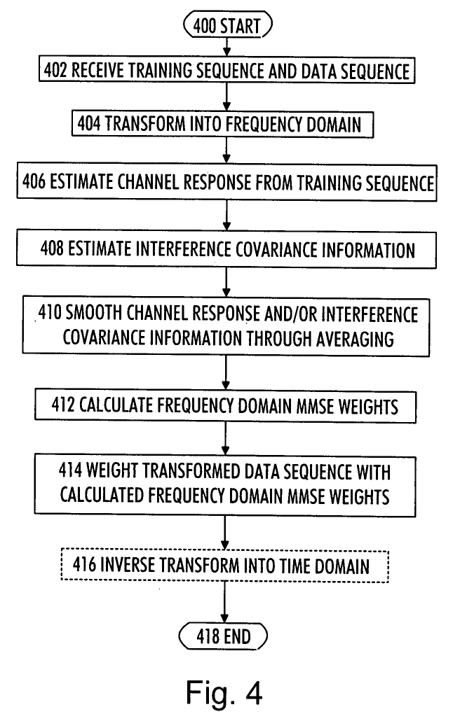

Next, an interference and channel estimation and suppression process according to an embodiment of the invention is described with reference to the flow diagram of FIG. 4. The process may be carried out in a radio receiver. The process starts in block 400. In block 402, a training sequence and a data sequence are received.

In block 404, the received training sequence and the data sequence are transformed into the frequency domain. In block 406, a channel response may be calculated from the received training sequence. The channel response may be estimated from the transformed training sequence or from the received, time-domain training sequence. In the latter case, the estimated channel response is an estimated channel impulse response which may then be transformed into the frequency domain. In block 408, interference parameters are estimated. The interference estimation may be carried out blindly, i.e. from the received data sequence without any knowledge of the transmitted signal, or from the received training sequence by removing the effect of the transmitted signal modified with the estimated channel response from the received training sequence. The estimation of the interference component may be carried out in the frequency domain from the transformed data sequence or from the transformed training sequence modified with the frequency domain channel response. The estimated interference parameters may comprise covariance information on the interference. Alternatively, the interference data samples may be calculated in the time domain by removing the effect of the pilot sequence modified with the estimated channel response from the received samples. In other words, the channel response may be calculated in the time domain and, subsequently, equation (12) may be calculated in time domain, too. The resulting interference samples may then be transformed into frequency domain, and the interference covariance matrix may be calculated according to equation (10) from the frequency domain interference samples. The aim is to calculate the interference covariance in frequency domain and, thus, the frequency domain interference data samples needed for calculation of the covariance information may be obtained in the time domain in the frequency domain. The time domain interference samples are naturally converted into the frequency domain.

The estimated channel response and/or the interference parameters may be smoothed through averaging in block 410. The received signal, from which the channel response and/or the interference parameters are estimated, may be divided into data blocks, each data block may be transformed into the frequency domain separately in block 404, estimation may be carried out in block 406 and/or 408, and the frequency-domain estimates of the data blocks may be averaged over the data blocks to obtain an averaged frequency-domain estimates. Additionally, or alternatively, the frequency domain estimates may be divided into a determined number of frequency sub-blocks, and the contents of each frequency sub-block may be averaged to smoothen the frequency-domain estimates and to reduce the number of estimated parameters. Blocks 408 and 410 may be carried out jointly by calculating equation (9) described above.

Then, frequency domain weights are calculated in block 412 according to equation (7) or (8). The calculated weights may fulfill the MSE criterion. In block 414, the received and transformed data sequence is weighted with the calculated weights in the frequency domain. The transformed data sequence may be multiplied with the calculated weights in order to obtain an interference-suppressed data sequence. The interference-suppressed data sequence may be transformed back into the time domain for demodulation and detection. If the demodulation and detection are carried out in the frequency domain, block 416 may be omitted. The process ends in block 418.

The embodiments of the invention may be realized in a radio receiver comprising a communication interface to receive radio signals and a processing unit operationally connected to the communication interface. The processing unit may be configured to perform at least some of the steps described in connection with the flowchart of FIG. 4 and in connection with FIGS. 2 and 3. The embodiments may be implemented as a computer program comprising instructions for executing a computer process for frequency domain interference rejection.

The computer program may be stored on a computer program distribution medium readable by a computer or a processor. The computer program medium may be, for example but not limited to, an electric, magnetic, optical, infrared or semiconductor system, device or transmission medium. The computer program medium may include at least one of the following media: a computer readable medium, a program storage medium, a record medium, a computer readable memory, a random access memory, an erasable programmable read-only memory, a computer readable software distribution package, a computer readable signal, a computer readable telecommunications signal, computer readable printed matter, and a computer readable compressed software package.

Even though the invention has been described above with reference to an example according to the accompanying drawings, it is clear that the invention is not restricted thereto but it can be modified in several ways within the scope of the appended claims.

1. A method, comprising:
receiving a signal comprising a training sequence and a data sequence;
estimating a channel response from the received training sequence and interference parameters from at least one of the received training sequence and the received data sequence;
smoothing a frequency spectrum of at least one of the estimated channel response and the estimated interference parameters through averaging;
calculating frequency domain interference suppression weights from the estimated channel response and the interference parameters, and
weighting the received data sequence with the calculated weights.

2. The method of claim 1, further comprising:
transforming the received training sequence and data sequence into a frequency domain, and
estimating the channel response and the interference parameters from at least one of the transformed training sequence and the transformed data sequence.

3. The method of claim 1, further comprising:
dividing the received sequence, from which the interference parameters are estimated, into a plurality of segments;
estimating the interference parameters for each segment separately, and wherein
the smoothing comprises averaging the estimated interference parameters.

4. The method of claim 3, further comprising:
calculating frequency domain covariance information for each transformed segment before averaging, and
calculating average frequency domain covariance information by averaging corresponding elements of the calculated frequency domain covariance information.

5. The method of claim 4, the calculation of the frequency domain covariance information comprising multiplying each element of the transformed segment with a complex conjugate of the element.

6. The method of claim 3, the smoothing further comprising:
dividing the averaged interference parameters into a plurality of frequency sub-blocks, and
averaging samples provided in each frequency sub-block to obtain an average value for each frequency sub-block.

7. The method of claim 1, further comprising:
dividing a frequency spectrum of at least one of the estimated channel response and the estimated interference parameters into a plurality of frequency sub-blocks; wherein
the smoothing comprises averaging samples provided in each frequency sub-block to obtain a single average value for each frequency sub-block.

8. The method of claim 7, further comprising:
assigning the average value for a determined number of frequency bins around a center frequency of a given frequency sub-block, and
interpolating values for frequency bins between the frequency bins of contiguous frequency sub-blocks from the average values of the contiguous frequency sub-blocks.

9. The method of claim 7, further comprising selecting, on the basis of knowledge of the bandwidths of interfering signals, the bandwidth of each frequency sub-block equal to or a multiple of the lowest of the bandwidths of the interfering signals.

10. The method of claim 1, further comprising:
dividing a frequency spectrum of the received training sequence into a plurality of frequency sub-blocks;
averaging samples provided in each frequency sub-block to obtain an average value for each frequency sub-block, and
estimating the channel response from the average values.

11. The method of claim 1, further comprising:
estimating the channel response before the interference parameters;
subtracting an effect of a known training sequence weighted with the estimated channel response from the received training sequence, thereby obtaining interference sequence, and
estimating the interference parameters from the interference sequence.

12. The method of claim 11, further comprising:
estimating the channel response in a time domain;
transforming the interference sequence from the time domain into a frequency domain, and
estimating the interference parameters from the transformed interference sequence.

13. The method of claim 1, further comprising:
receiving the received signal through a plurality of diversity branches;
estimating the channel response and the interference parameters for each diversity branch;
calculating frequency domain interference suppression weights from the estimated channel responses and the interference parameters, and
weighting the received data sequence in each diversity branch with the calculated weights.

14. The method of claim 13, wherein the received signal is received through a plurality of reception antennas, and a signal received through an antenna forms a diversity branch.

15. The method of claim 13, wherein the received signal is over-sampled with a determined oversampling factor, and the oversampling factor defines the number of diversity branches.

16. An apparatus, comprising:
an interface to receive a signal comprising a training sequence and a data sequence, and
a processing unit configured to estimate a channel response from the received training sequence and interference parameters from at least one of the received training sequence and the received data sequence, to smooth a frequency spectrum of at least one of the estimated channel response and the estimated interference parameters through averaging, to calculate frequency domain interference suppression weights from the estimated channel response and the interference parameters, and to weight the received data sequence with the calculated weights.

17. The apparatus of claim 16, wherein the processing unit is further configured to transform the received training sequence and data sequence into a frequency domain and to estimate the channel response and the interference parameters from at least one of the transformed training sequence and the transformed data sequence.

18. The apparatus of claim 16, wherein the processing unit is further configured to divide the received sequence, from which the interference parameters is estimated, into a plurality of segments, to estimate the interference parameters for each segment separately, and to perform the smoothing by averaging the estimated interference parameters.

19. The apparatus of claim 18, wherein the processing unit is further configured to calculate frequency domain covariance information for each transformed segment before averaging, and calculate average frequency domain covariance information by averaging corresponding elements of the calculated frequency domain covariance information.

20. The apparatus of claim 19, wherein the processing unit is further configured to calculate the frequency domain covariance information for a transformed segment by multiplying each element of the transformed segment with a complex conjugate of the element.

21. The apparatus of claim 18, wherein the processing unit is configured to further smooth the averaged interference parameters by dividing the averaged interference parameters into a plurality of frequency sub-blocks, and averaging samples provided in each frequency sub-block to obtain an average value for each frequency sub-block.

22. The apparatus of claim 16, wherein the processing unit is further configured to divide the frequency spectrum of at least one of the estimated channel response and the estimated interference parameters into a plurality of frequency sub-blocks and to perform the smoothing by averaging samples provided in each frequency sub-block to obtain a single average value for each frequency sub-block.

23. The apparatus of claim 22, wherein the processing unit is further configured to assign the average value for a determined number of frequency bins around a center frequency of a given frequency sub-block and to interpolate values for frequency bins between the frequency bins of contiguous frequency sub-blocks from the average values of the contiguous frequency sub-blocks.

24. The apparatus of claim 22, wherein the interface is configured to select, on the basis of knowledge of the bandwidths of interfering signals, the bandwidth of each frequency sub-block equal to or a multiple of the lowest of the bandwidths of the interfering signals.

25. The apparatus of claim 16, wherein the processing unit is further configured to divide a frequency spectrum of the received training sequence into a plurality of frequency sub-blocks, to average samples provided in each frequency sub-block to obtain an average value for each frequency sub-block, and to estimate the channel response from the average values.

26. The apparatus of claim 16, wherein the processing unit is further configured to estimate the channel response before the interference parameters, subtract an effect of a known training sequence weighted with the estimated channel response from the received training sequence, thereby obtaining an interference sequence, and estimate the interference parameters from the interference sequence.

27. The apparatus of claim 26, wherein the processing unit is further configured to estimate the channel response in a time domain, to transform the interference sequence from the time domain into a frequency domain, and to estimate the interference parameters from the transformed interference sequence.

28. The apparatus of claim 16, wherein the interface is configured to receive the received signal through a plurality of diversity branches and the processing unit is further configured to estimate the channel response and the interference parameters for each diversity branch, calculating frequency domain interference suppression weights from the estimated channel responses and the interference parameters, and weight the received data sequence in each diversity branch with the calculated weights.

29. The apparatus of claim 28, wherein the interface is configured to receive the received signal through a plurality of reception antennas, and a signal received through an antenna forms a diversity branch.

30. The apparatus of claim 28, wherein the interface is configured to oversample the received signal with a determined oversampling factor, and the oversampling factor defines the number of diversity branches.

31. An apparatus, comprising:
means for receiving a signal comprising a training sequence and a data sequence;
means for estimating a channel response from the received training sequence and interference parameters from at least one of the received training sequence and the received data sequence;
means for smoothing a frequency spectrum of at least one of the estimated channel response and the estimated interference parameters through averaging;
means for calculating frequency domain interference suppression weights from the estimated channel response and the interference parameters, and
means for weighting the received data sequence with the calculated weights.

32. A computer program distribution medium readable by a computer and encoding a computer program of instructions for executing a computer process for interference rejection, the process comprising:
receiving a signal comprising a training sequence and a data sequence;
estimating a channel response from the received training sequence and interference parameters from at least one of the received training sequence and the received data sequence;
smoothing a frequency spectrum of at least one of the estimated channel response and the estimated interference parameters through averaging;
calculating frequency domain interference suppression weights from the estimated channel response and the interference parameters, and
weighting the received data sequence with the calculated weights.

33. The computer program distribution medium of claim 32, the distribution medium including at least one of the following media: a computer readable medium, a program storage medium, a record medium, a computer readable memory, a computer readable software distribution package, a computer readable signal, a computer readable telecommunications signal, and a computer readable compressed software package.
